(19) United States
(12) Patent Application Publication
(10) Pub. No.: US 2009/0107955 A1
(43) Pub. Date: Apr. 30, 2009

(54) OFFSET LINER FOR CHAMBER EVACUATION

(76) Inventors: ROBIN L. TINER, Santa Cruz, CA (US); Suhail Anwar, San Jose, CA (US); Gaku Furuta, Sunnyvale, CA (US); Young Jin Choi, Santa Clara, CA (US); Beom Soo Park, San Jose, CA (US); Soo Young Choi, Fremont, CA (US); John M. White, Hayward, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/205,414

(22) Filed: Sep. 5, 2008

Related U.S. Application Data
(60) Provisional application No. 61/086,747, filed on Aug. 6, 2008.
(60) Provisional application No. 60/983,066, filed on Oct. 26, 2007.

(51) Int. Cl. B44C 1/22; C23C 16/455; C23C 16/44; C23F 1/08

(52) U.S. Cl. 216/67; 118/715; 427/248.1; 427/569; 156/345.35

(57) ABSTRACT

The present invention generally includes a chamber liner spaced from a chamber wall to permit processing gases to be pulled between the chamber liner and the chamber wall when withdrawing gases from the processing chamber. When the vacuum pump is below the susceptor, processing gases will be drawn below the susceptor and may lead to undesired deposition onto process chamber components. Additionally, the processing gases will be pulled past the slit valve opening and potentially deposit within the slit valve opening. When material deposits in the slit valve opening, flaking may occur and contaminate the substrates. By drawing the processing gases along the sidewalls other than the one having the slit valve opening therethrough, undesired deposition on the slit valve opening may be reduced.

### CROSS-REFERENCE TO RELATED APPLICATIONS

This application claims benefit of U.S. Provisional Patent Application Ser. No. 61/086,747 (APPM/012628L02), filed Aug. 6, 2008 and U.S. Provisional Patent Application Ser. No. 60/983,066 (APPM/012628L), filed Oct. 26, 2007, both of which are herein incorporated by reference.

### BACKGROUND OF THE INVENTION

1. Field of the Invention

Embodiments of the present invention generally relate to a processing chamber having an evacuation plenum between a chamber liner and a chamber wall.

2. Description of the Related Art

When processing substrates in a vacuum, a vacuum pump is used to evacuate the processing chamber to the appropriate processing pressure. In some cases, the vacuum pump will continually evacuate processing gases introduced into the processing chamber to maintain a desired processing pressure. The vacuum pump will pull the processing gases through the processing chamber to the vacuum pump port leading to the vacuum pump.

Processing gases, such as deposition gases, are introduced into the processing chamber and, during processing, may lead to deposition on exposed chamber components. Deposition on undesired chamber components may lead to component failure or substrate contamination during processing. When a component fails, the component will need to either be cleaned or replaced. In either case, the processing chamber will need to be shut down to access the component, which leads to a decrease in substrate throughput.

Therefore, there is a need in the art for a processing chamber having an evacuation system that reduces processing chamber component failure and substrate contamination.

### SUMMARY OF THE INVENTION

The present invention generally includes a chamber liner spaced from a chamber wall to permit processing gases to be pulled between the chamber liner and the chamber wall when withdrawing gases from the processing chamber. In one embodiment, an apparatus comprises a chamber body having a slit valve opening formed through a first side and one or more ledges coupled to the chamber body. The one or more ledges extend from the first side above the slit valve opening at a first distance from a bottom of the chamber. The apparatus also includes a first chamber liner coupled to at least a second side of the chamber body adjacent the first side. The first chamber liner has a first liner portion spaced from the second side and from a bottom of the chamber. The first liner portion extends to a first height within the chamber body substantially equal to the first distance. The apparatus also comprises a shadow frame disposed within the chamber body and movable between a first position in contact with the first chamber liner and the one or more ledges and a second position spaced from the first chamber liner and the one or more ledges.

In another embodiment, an apparatus comprises a liner assembly. The liner assembly includes a first side having a slit valve opening therethrough, a first top surface, and a first bottom surface. The liner assembly also includes a second side having a second top surface at substantially the same elevation as the first top surface and a second bottom surface having an elevation above the first bottom surface. The second side also has an upper portion and a bottom portion spaced therefrom and coupled together at ends of the second side. The apparatus also may include a shadow frame movable between a first position in contact with the liner assembly and a second position spaced form the liner assembly. The shadow frame has a first width that is substantially equal along three sides thereof and a second width along a fourth side thereof that is greater than the first width.

In another embodiment, a method is disclosed. The method includes raising a susceptor from a lowered position to a raised position, lifting a shadow frame from a first position in contact with a chamber liner to a second position in contact with the susceptor and spaced from the chamber liner such that a first distance between the chamber liner and a chamber wall is greater than a second distance between the shadow frame and the chamber liner. The method also includes pulling processing gas around the shadow frame and between the liner and the chamber wall to an area under the susceptor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a cross sectional view of a plasma enhanced chemical vapor deposition (PECVD) apparatus according to one embodiment of the invention.

FIG. 1B is a cross sectional view of the PECVD apparatus of FIG. 1A with the susceptor in the processing position.

FIG. 1C is a schematic top view of the shadow frame of FIG. 1A.

FIG. 2A is a schematic top view of an apparatus having an offset liner according to one embodiment of the invention.

FIG. 2B is a schematic top view of an apparatus having an offset shadow frame according to another embodiment of the invention.

FIG. 3 is a schematic sectional view of an apparatus having an offset liner and shadow frame according to another embodiment of the invention.

FIG. 4 is a cross sectional view of a PECVD apparatus according to one embodiment of the invention.

FIG. 5 is another sectional view of a processing apparatus having a double wall evacuation channel according to one embodiment of the invention.

FIG. 6 is a partial schematic isometric view of a slit valve opening in a processing chamber having a double wall evacuation channel according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally includes a chamber liner spaced from a chamber wall to permit processing gases to be pulled between the chamber liner and the chamber wall when withdrawing gases from the processing chamber. The invention will be described below in relation to a PECVD apparatus. A suitable PECVD apparatus may be purchased from AKT America, Inc., a wholly owned subsidiary of Applied Materials, Inc., Santa Clara, Calif. It is to be understood that the invention described below may be utilized in other processing chambers such as etching or physical vapor deposition (PVD) chambers, including those sold by other manufacturers.

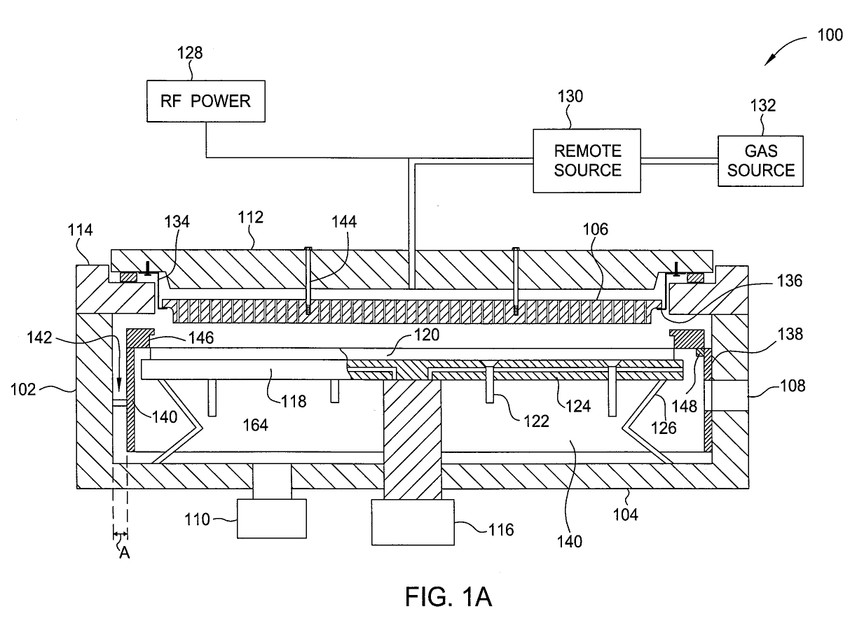

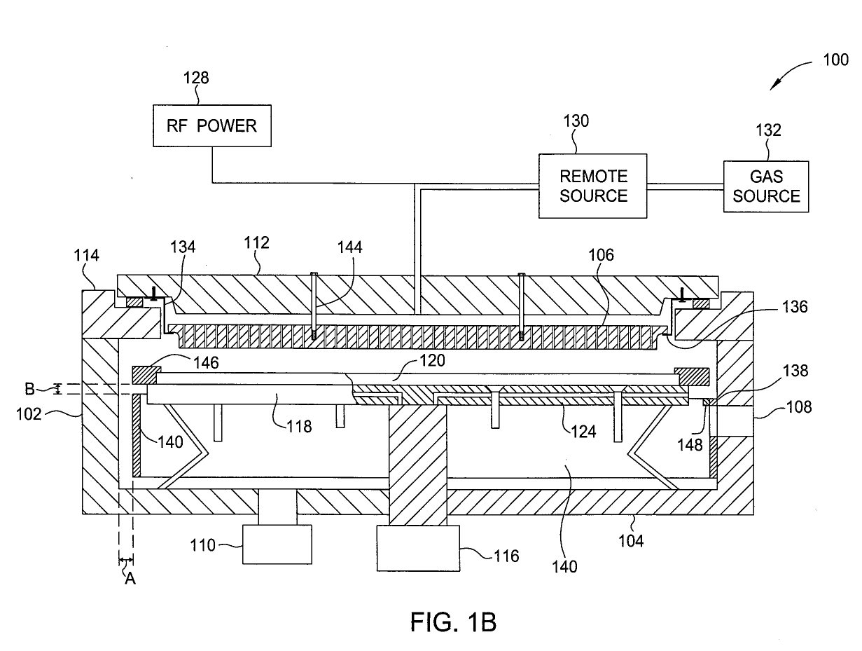

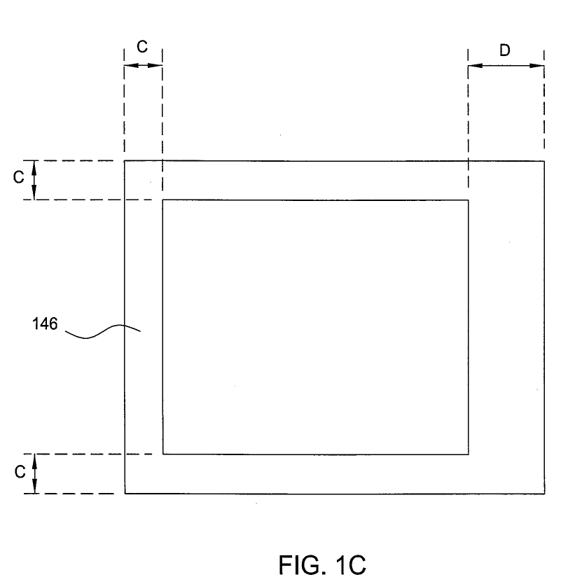

FIG. 1A is a cross sectional view of a PECVD apparatus according to one embodiment of the invention. The PECVD apparatus includes a chamber 100 having walls 102 and a bottom 104. A showerhead 106 and susceptor 118 are disposed in the chamber 100 and bound a process volume therebetween. The process volume is accessed through a slit valve opening 108 such that the substrate 120 may be transferred in and out of the chamber 100. The susceptor 118 may be coupled to an actuator 116 to raise and lower the susceptor 118. Lift pins 122 are moveably disposed through the susceptor 118 to support a substrate 120 prior to placement onto the susceptor 118 and after removal from the susceptor 118. The susceptor 118 may also include heating and/or cooling elements 124 to maintain the susceptor 118 at a desired temperature.

Grounding straps 126 may be coupled to the susceptor 118 to provide RF grounding at the periphery of the susceptor 118. The grounding straps 126 may be coupled to the bottom 104 of the chamber 100. In one embodiment, the grounding straps 126 may be coupled to the corners and/or sides of the susceptor 118 and the bottom 104 of the chamber 100.

The showerhead 106 is coupled to a backing plate 112 by a coupling 144. In one embodiment, the coupling 144 may comprise a bolt threadedly engaged with the showerhead 106. The showerhead 106 may be coupled to the backing plate 112 by one or more couplings 144 to help prevent sag and/or control the straightness/curvature of the showerhead 106. In one embodiment, twelve couplings 144 may be used to couple the showerhead 106 to the backing plate 112. The showerhead 106 may additionally be coupled to the backing plate 112 by a bracket 134. The bracket 134 may have a ledge 136 upon which the showerhead 106 may rest. The backing plate 112 may rest on a ledge 114 coupled with the chamber walls 102 to seal the chamber 100.

The spacing between the top surface of the susceptor 118 and the showerhead 106 may be between about 400 mil and about 1,200 mil. In one embodiment, the spacing may be between about 400 mil and about 800 mil.

A gas source 132 is coupled to the backing plate 112 to provide gas through gas passages in the showerhead 106 to the substrate 120. A vacuum pump 110 is coupled to the chamber 100 at a location below the susceptor 118 to maintain the process volume at a predetermined pressure. A RF power source 128 is coupled to the backing plate 112 and/or to the showerhead 106 to provide a RF power to the showerhead 106. The RF power creates an electric field between the showerhead 106 and the susceptor 118 so that a plasma may be generated from the gases between the showerhead 106 and the susceptor 118. Various frequencies may be used, such as a frequency between about 0.3 MHz and about 200 MHz. In one embodiment, the RF power is provided at a frequency of 13.56 MHz.

A remote plasma source 130, such as an inductively coupled remote plasma source, may also be coupled between the gas source 132 and the backing plate 112. Between processing substrates, a cleaning gas may be provided to the remote plasma source 130 so that a remote plasma is generated. Radicals from the remotely generated plasma may then be provided to the chamber 100 to clean components of the chamber 100. The cleaning gas may be further excited by power provided by the RF power source 128 to the showerhead 106. Suitable cleaning gases include but are not limited to NF₃, F₂, and SF₆.

The processing chamber 100 may also comprise a chamber liner 138 that is flush against the wall 102 having the slit valve opening 108. The chamber liner 138 may be coupled to the wall 102 by a fastening mechanism such as an adhesive, a nut and bolt assembly, or a screw. As shown in FIG. 1A, the chamber liner 138 may extend all the way to the bottom 104 of the chamber 100 and be coupled thereto. Because the chamber liner 138 is flush against the wall 102 having the slit valve opening 108 therethrough, substantially no processing gases may be drawn down behind the liner 138 by the vacuum pump 110.

A chamber liner 140 may also be present on the remaining three walls 102 of the chamber 100. The chamber liner 140 may be spaced a distance “A” from the walls 102 such that a plenum 142 is defined between the walls 102 and the liner 140. The liner 140 may be spaced from the bottom 104 of the chamber 100 to permit any gases in the plenum 142 to be pulled down the plenum 142 to the vacuum pump 110. In one embodiment, the liners 138, 140 may comprise aluminum. In another embodiment, the liners 138, 140 may comprise anodized aluminum. In another embodiment, the liners 138, 140 may comprise stainless steel. In another embodiment, the liners 138, 140 may comprise an electrically insulating material.

The top of the chamber liner 140 may be used to support a shadow frame 146 when the susceptor 118 is in the lowered position as shown in FIG. 1A. The shadow frame 146 may also rest on a ledge 148 that extends from the wall 102 having the slit valve opening 108 formed therethrough. Alternatively, the ledge 148 may extend from the liner 138. The top of the liner 138 may be at an elevation substantially equal to the top of the liner 140 such that the shadow frame 146 is substantially level.

When the susceptor 118 is in the processing position as shown in FIG. 1B, the shadow frame 146 is spaced a distance “B” from the liner 140 and the ledge 138. The distance “B” that the shadow frame 146 is spaced from the liner 140 and the ledge 148 is smaller than a width of the plenum 142 as shown by the arrow “A”. Therefore, a greater amount of processing gas will be drawn through the plenum 142 as opposed to between the shadow frame and the liner 140 or the shadow frame 146 and the ledge 148. Thus, little or no processing gas may be pulled down under the susceptor and in front of the slit valve opening 108. In one embodiment, the ratio of “A” to “B” is between about 2:1 to about 20:1. Accordingly, little or no processing gas may be pulled between the shadow frame 146 and the liner 140. Therefore, little if any material may deposit under the susceptor 118 which could flake off during susceptor 118 movement. With little or no processing gas pulled in front of the slit valve opening 108, less material may deposited within the slit valve opening 108 which could flake off and contaminate the substrate 120.

In one embodiment, the shadow frame 146 may be symmetrically disposed within the chamber 100. In another embodiment, the shadow frame 146 may be asymmetrically disposed such that the shadow frame 146 extends a greater distance towards the wall 102 having the slit valve opening 108 therethrough as compared to the other walls 102. FIG. 1C is a schematic top view of the shadow frame of FIG. 1A showing the width of the shadow frame 146 at the slit valve opening side (represented by arrows “D”) being greater than the width of the other sides of the shadow frame 146 (represented by arrows “C”). The asymmetrical shadow frame 146 may reduce the space between the shadow frame 146 and the chamber walls and thus reduce the amount of gas pulled between the shadow frame and the wall on the slit valve side of the chamber.

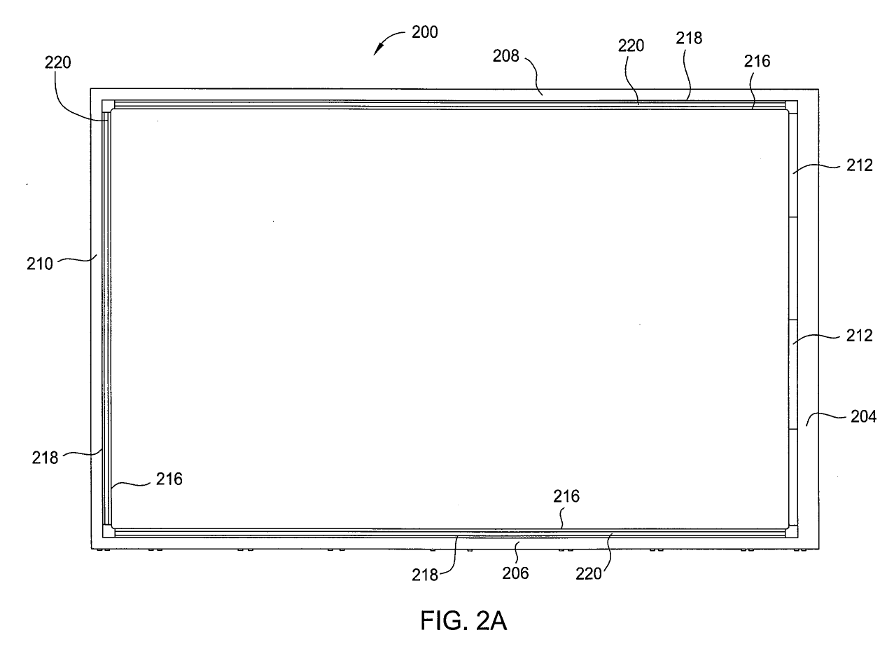

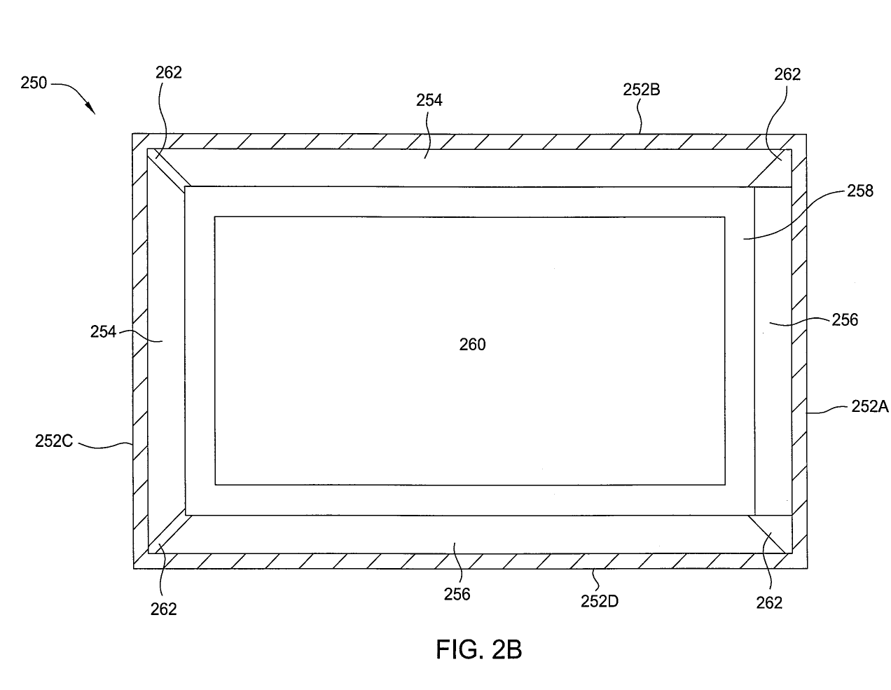

FIG. 2A is a schematic section of a chamber having an offset liner according to one embodiment of the invention. The chamber 200 may have a first wall 204 having a slit valve opening therethrough. The chamber 200 may also have three other walls 206, 208, 210. On the slit valve wall 204, the liner, which is hidden by the ledge 212, may be flush against the chamber wall 204 such that no space is present between the liner and the wall 204. A ledge 212 may be present above the slit valve opening to permit the shadow frame to rest thereon when the susceptor is in the lowered position. The ledge 212 may comprise a plurality of pieces that are spaced apart such as shown as ledges 214 on wall 210 as shown in FIG. 2A.

In one embodiment, three walls have chamber liners that are substantially identical. In another embodiment, the chamber liner that covers the three walls may comprise a single piece. In one embodiment, the ledge 212 may comprise a single piece of material that spans the length of the slit valve opening. In another embodiment, the ledge 212 may comprise a plurality of pieces that collectively span the length of the slit valve opening. The ledge 212 may reduce the amount of processing gas that travels into the slit valve opening.

Along walls 206, 208, a liner portion 216 may be present that is spaced from the walls 206, 208. Additionally, a liner portion 218 may be present that is flush against the walls 206, 208 such that no processing gas may travel between the liner portion 218 and the chamber walls 206, 208. A plenum 220 is present between the liner portion 216 and the chamber walls 206, 208 to permit processing gas to flow therethrough. Notches may be present on the bottom of the liner portion 216 to permit grounding straps to couple thereto if desired. In one embodiment, wall 210 may have a liner flush against the wall 210 such that no processing gas may flow between the liner and the wall 210. The liner portion 216 and liner portion 218 may be coupled together at the corners thereof. Additionally, at the location where the liner portions 216, 218 couple together, the liner portions 216, 218 may be coupled to the walls 206, 208 of the chamber 200.

FIG. 2B is a schematic top view of an apparatus having an offset shadow frame according to another embodiment of the invention. The apparatus 250 has a plurality of chamber walls 252A-D that enclose an offset shadow frame 258. The shadow frame 258 has an opening therethrough to permit the substrate 260 to be exposed to processing gases during processing. The shadow frame 258 may rest on the liner that is spaced from the walls 252B-D. The liner may be coupled to the walls 252A-D by couplings 262. In one embodiment, the couplings 262 may comprise one or more rods that extend from the walls 252A-D that are welded to the liner and to the walls 252A-D. In another embodiment, the couplings 262 may be releasably coupled to the walls 252A-D and to the liner.

On the slit valve side wall 252A, a ledge 256 may extend from the wall 252A above the slit valve opening. The shadow frame 258 may rest on the ledge 256 when not raised in the processing position. The shadow frame 258 is spaced from the walls 252B-D such that the bottom 254 of the chamber is visible. On the slit valve side wall 252A, however, the ledge 256 and the shadow frame 258 block any line of sign path to the chamber bottom 254. The shadow frame 258 is therefore offset due to the greater width of the shadow frame 258 along the slit valve side wall 252A as compared to the other walls 252B-D. Thus, any processing gas that is evacuated out of the apparatus 250 through the chamber bottom 254 may travel a tortuous path around the shadow frame 258 and the ledge 256. Due to the tortuous path, the processing gas will naturally take the path of least resistance. The path of least resistance is the path between liners and the walls 252B-D.

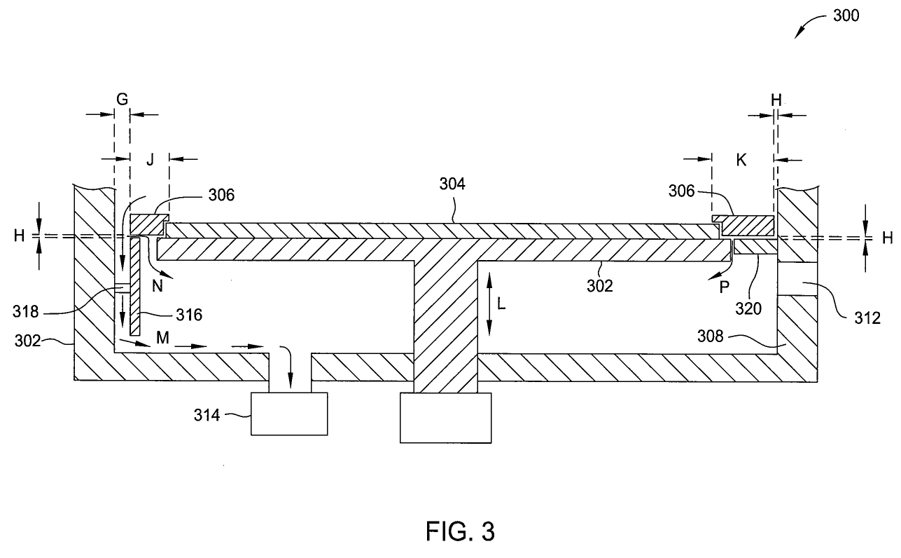

FIG. 3 is a schematic sectional view of an apparatus 300 having an offset liner 316 and shadow frame 306 according to another embodiment of the invention. The apparatus 300 has a susceptor 302 that may raise and lower as shown by arrows “L”. A substrate 304 may be disposed on the susceptor 302. A shadow frame 306 may be lifted from a ledge 320 and from on top of a liner 316 to a processing position. The shadow frame 306 may be an offset shadow frame 306 such that the width (represented by arrows “K”) of the shadow frame 306 adjacent to the wall 308 having the slit valve opening 312 is greater than the width (represented by arrows “J”) adjacent the other walls 308. In one embodiment, the distance that the shadow frame 306 is spaced from the wall 308 having the slit valve opening 312 therethrough (represented by arrows “H”) is about equal to the distance that the shadow frame 306 is raised above the ledge 320 and liner 316 (represented by arrows “H”). The distance that the liner 316 is spaced from the wall 308 by a coupling 318 is shown by arrows “G”. In one embodiment, the ratio of “G” to “H” is between about 2:1 to about 20:1. Therefore, the processing gas evacuated by the vacuum pump 314 may travel the path of least resistance (i.e., between the liner 316 and the wall) as shown by arrows “M”. The path between the liner 316 and the wall 308 is far less tortuous than the path between the shadow frame 306 and the liner as shown by arrows “N” or the path between the shadow frame 306 and the ledge 320 as shown by arrows “P”. Thus, a greater amount of gas will be evacuated between the liner 316 and the wall 308 away from the slit valve opening 312 and the underside of the susceptor 302 which may reduce deposition on undesired chamber surfaces.

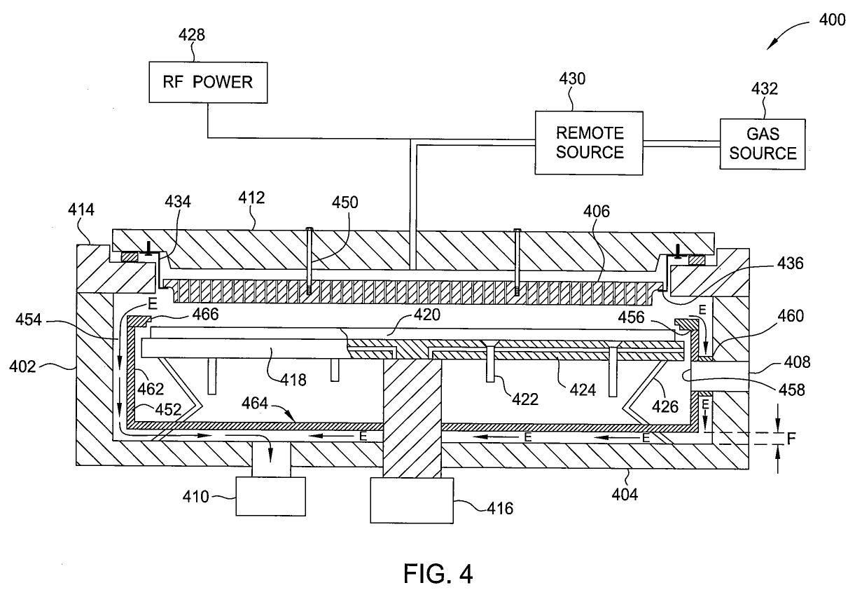

FIG. 4 is a cross sectional view of a PECVD apparatus according to another embodiment of the invention. The apparatus includes a chamber 400 in which one or more films may be deposited onto a substrate 420. The chamber 400 generally includes walls 402 and a bottom 404. A showerhead 406 and susceptor 418 are disposed in a process volume defined by the chamber 400. The process volume is accessed through a slit valve opening 408 such that the substrate 420 may be transferred in and out of the chamber 400. The susceptor 418 may be coupled to an actuator 416 to raise and lower the susceptor 418. Lift pins 422 are moveably disposed through the susceptor 418 to support a substrate 420 prior to placement onto the susceptor 418 and after removal from the susceptor 418. The susceptor 418 may also include heating and/or cooling elements 424 to maintain the susceptor 418 at a desired temperature. The susceptor 418 may also include grounding straps 426 to provide RF grounding at the periphery of the susceptor 418.

The showerhead 406 is coupled to a backing plate 412 by a fastening mechanism 450. The showerhead 406 may be coupled to the backing plate 412 by one or more coupling supports 450 to help prevent sag and/or control the straightness/curvature of the showerhead 406. In one embodiment, twelve coupling supports 450 may be used to couple the showerhead 406 to the backing plate 412. The coupling supports 450 may include a fastening mechanism such as a nut and bolt assembly. In one embodiment, the nut and bolt assembly may be made with an electrically insulating material. In another embodiment, the bolt may be made of a metal and surrounded by an electrically insulating material. In still another embodiment, the showerhead 406 may be threaded to receive the bolt. In yet another embodiment, the nut may be formed of an electrically insulating material. The electrically insulating material helps to prevent the coupling supports 450 from becoming electrically coupled to any plasma that may be present in the chamber 400. Additionally and/or alternatively, a center coupling mechanism may be present to couple the backing plate 412 to the showerhead 406. The center coupling mechanism may surround a backing plate support ring (not shown) and be suspended from a bridge assembly (not shown). The showerhead 406 may additionally be coupled to the backing plate 412 by a bracket 434. The bracket 434 may have a ledge 436 upon which the showerhead 406 may rest. The backing plate 412 may rest on a ledge 414 coupled with the chamber walls 402 to seal the chamber 400.

A gas source 432 is coupled to the backing plate 412 to provide gas through gas passages in the showerhead 406 to the substrate 420. A vacuum pump 410 is coupled to the chamber 400 at a location below the susceptor 418 to maintain the process volume at a predetermined pressure. A RF power source 428 is coupled to the backing plate 412 and/or to the showerhead 406 to provide a RF power to the showerhead 406. The RF power creates an electric field between the showerhead 406 and the susceptor 418 so that a plasma may be generated from the gases between the showerhead 406 and the susceptor 418. Various frequencies may be used, such as a frequency between about 0.3 MHz and about 200 MHz. In one embodiment, the RF power is provided at a frequency of 13.56 MHz.

A remote plasma source 430, such as an inductively coupled remote plasma source 430, may also be coupled between the gas source 432 and the backing plate 412. Between processing substrates, a cleaning gas may be provided to the remote plasma source 430 so that a remote plasma is generated. Radicals from the remotely generated plasma may be delivered to the chamber 400 to clean the chamber 400 components. The cleaning gas may be further excited by the RF power source 428 provided to the showerhead 406. Suitable cleaning gases include by are not limited to NF₃, F₂, and SF₆.

The processing chamber 400 may also comprise an evacuation body 452 disposed inside the processing chamber 400. The evacuation body 452 has a plurality of sidewalls 462 coupled to a bottom 464. The evacuation body 452 at least partially encloses a processing space of the chamber 400. The evacuation body 452 may be disposed within the processing chamber 400 such that an evacuation channel 454 is formed between the chamber walls 402 and the evacuation body 452. The height of the sidewalls 462 is less than the height of the chamber walls 402 such that an entrance to the evacuation channel 454 is formed above the top 456 of the sidewalls 462. The entrance to the evacuation channel 454 is disposed above the susceptor 418 when the susceptor 418 is in the lowered position to receive a substrate 420. When the substrate 420 is in the raised position for processing, the entrance to the evacuation channel 454 is below the raised or processing position where the substrate is processed. The evacuation channel 454 may have a width “F” (shown by arrows) that is sufficient to allow the pressure of the chamber 400 to be maintained at a predetermined pressure. The evacuation body 452 may be coupled to the wall 402 of the chamber 400 to ground the evacuation body 452. Additionally, the grounding straps 426 may be coupled with the evacuation body 452 to provide a path to ground. Alternatively, grounding straps 426 may be directly connect to the bottom of chamber 404.

A shadow frame 466 may be disposed on the top 456 of the sidewalls 462 of the evacuation body 452. As the susceptor 418 is raised to the processing position, the susceptor 418 encounters the shadow ring 466 and lifts the shadow ring 466 off of the top 456 of the sidewalls 462 of the evacuation body 452. Thus, when the susceptor 418 is in the processing position, the shadow ring 466 is decoupled from the top 456 of the sidewalls 462 of the evacuation body 452, and the entrance to the evacuation channel 454 is below the now raised top surface of the susceptor 418.

Processing gases that are evacuated from the chamber 400 are pulled into the evacuation channel 454 and follow the path shown by arrows “E” to the vacuum pump 410. The processing gases are drawn into the evacuation channel 454 such that the amount of processing gases pulled to the area below the susceptor 418 is reduced. Because the amount of processing gases that reach the area below the susceptor 418 is reduced, the amount of deposition upon chamber components below the susceptor 418 is also reduced. Additionally, in the case of etching, the erosion of chamber components below the susceptor 418 is also reduced, thereby extending the life of chamber components.

The top 456 of the evacuation body 452 may also be disposed above the chamber-side opening 458 of the slit valve opening 408. Because the top 456 of the evacuation body 452 is above the chamber-side opening 458 of the slit valve opening 408, processing gases will be drawn around the chamber-side opening 458 into the evacuation channel 454. Processing gases may be drawn into the evacuation channel 454 from below the susceptor 418 as well. The amount of processing gases that enter the chamber-side opening 458 of the slit valve opening 408 may be reduced because the processing gases, as they are evacuated, are drawn away from the side pumping plenum “E” of the slit valve opening 408. When processing gases do not enter the chamber-side opening 458 of the slit valve opening 408, the amount of material deposited within a slit valve tunnel 460 defined through the body 452 and wall 402 may be reduced. When less material deposits within the slit valve tunnel 460, flaking of material deposited within the slit valve tunnel 460 may be reduced and hence, substrate contamination may also be reduced.

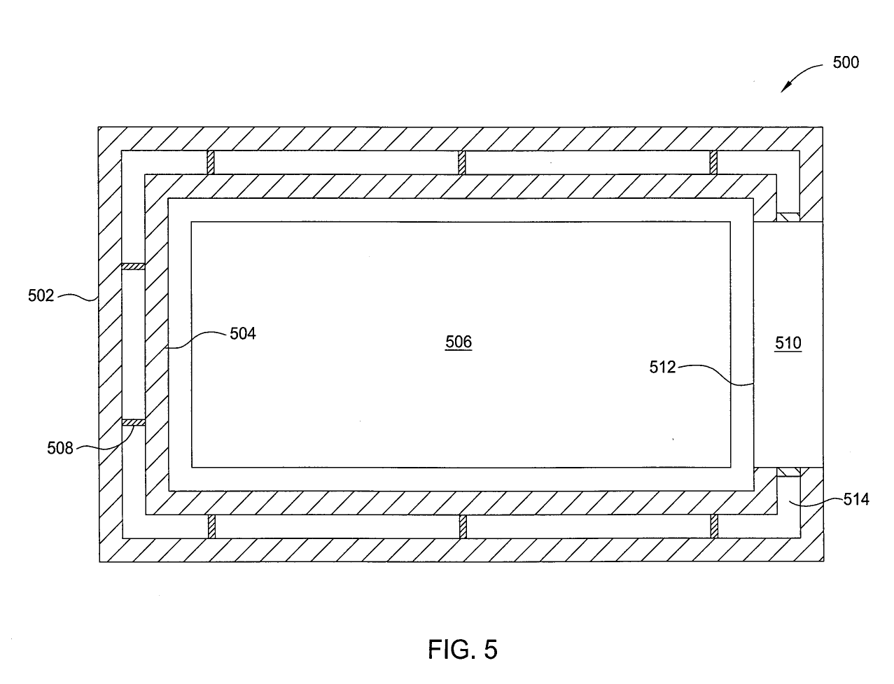

FIG. 5 is a schematic horizontal sectional view of a processing chamber 500 having a double wall evacuation channel 514 according to one embodiment of the invention. The chamber 500 comprises an outer wall 502 that at least partially encloses the processing area of the processing chamber 500. An evacuation body is also present having an inner wall 504 coupled to the outer wall 502 by a coupling 508. The coupling 508 may comprise a weld, a fastening mechanism such as a threaded fastener, or other suitable coupling mechanism. Between the outer wall 502 and the inner wall 504, an evacuation channel 514 is defined. The evacuation channel 514 has an opening to the processing zone that is above the level of both the susceptor 506 and the slit valve opening 512. The evacuation channel permits the vacuum pump (not shown), to draw a vacuum through the channel 514 without pulling the processing gases below the area of the susceptor 506 or the slit valve opening 512. Because of the location where the processing gases are pulled into the evacuation channel 514, the amount of processing gases that may reach the area below the susceptor 506 may be reduced. Additionally, because the entrance to the evacuation channel 514 is above the slit valve opening 512, the amount of processing gases drawn into the slit valve tunnel 510 may be reduced and hence, so may flaking of contaminates onto incoming or outgoing substrates passing through the slit valve tunnel 510. As can be seen from FIG. 5, the slit valve tunnel 510 passes through the evacuation channel 514. Thus, processing gases drawn through the evacuation channel 514 may pass around the outside of the slit valve tunnel 510.

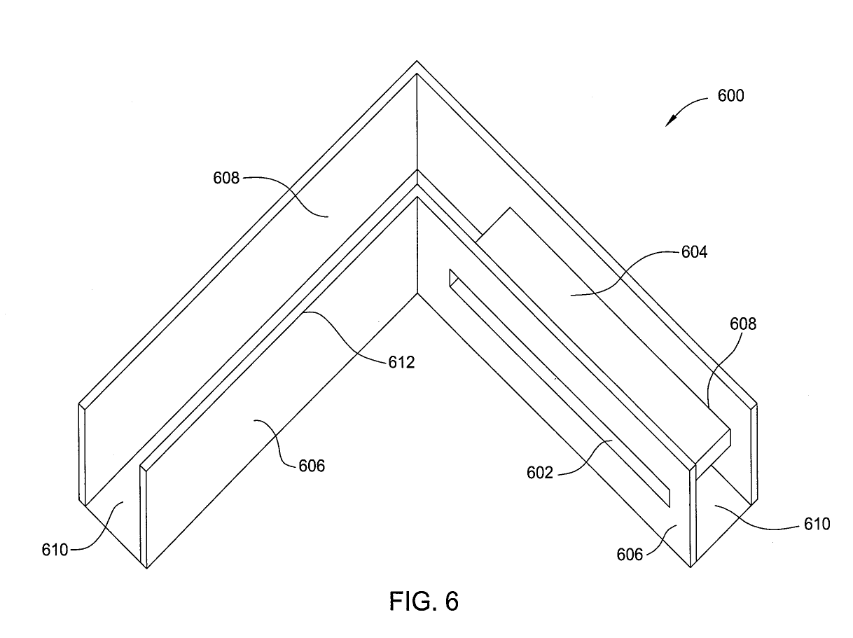

FIG. 6 is a partial schematic isometric view of a slit valve opening 602 in a processing chamber 600 having a double wall evacuation channel according to one embodiment of the invention. The chamber 600 comprises a plurality of outer walls 608 that at least partially encloses a processing area of the chamber 600. The chamber 600 also comprises an evacuation body having a plurality of inner walls 606. The inner walls 606 may be coupled with the outer walls 608 by one or more couplings (not shown) and the chamber bottom 610. Between the inner walls 606 and the outer walls 608, an evacuation channel is defined through which processing gases will be evacuated. The evacuation channel is bound by the inner wall 606, outer wall 608, and chamber bottom 610. The evacuation channel is opened at the top to permit processing gases to enter the channel. The slit valve tunnel 604 is coupled to the inner wall 606 and the passes through the evacuation channel such that the processing gases evacuated flow around the outside of the slit valve tunnel 604. The top 612 of the inner wall 606 is the entrance to the evacuation channel. Thus, the processing gases being evacuated enter the evacuation channel at a location above the slit valve opening 602. Therefore, the amount of processing gases that enter into the slit valve tunnel 604 through the slit valve opening 602 is reduced. When processing gases do not enter into the slit valve tunnel 604, the processing gases do not deposit on the surfaces of the slit valve tunnel 604 and flake off onto incoming and/or outgoing substrates passing through the slit valve tunnel 604.

By withdrawing processing gases from the processing chamber at a location along the sidewall of the chamber, material deposition onto chamber components below the susceptor may be reduced and hence, cleaning and/or replacement of the chamber components may be reduced. By reducing the cleaning and/or replacement of chamber components, chamber downtime may be reduced and substrate throughput may be increased.

While the foregoing is directed to embodiments of the present invention, other and further embodiments of the invention may be devised without departing from the basic scope thereof, and the scope thereof is determined by the claims that follow.

1. An apparatus, comprising:
a chamber body having a slit valve opening formed through a first side;
one or more ledges coupled to the chamber body and extending from the first side above the slit valve opening at a first distance from a bottom of the chamber;
a first chamber liner coupled to at least a second side of the chamber body adjacent the first side, the first chamber liner having a first liner portion spaced from the second side and from a bottom of the chamber, the first liner portion extending to a first height within the chamber body substantially equal to the first distance; and
a shadow frame disposed within the chamber body and movable between a first position in contact with the first chamber liner and the one or more ledges and a second position spaced from the first chamber liner and the one or more ledges.

2. The apparatus of claim 1, further comprising a second chamber liner flush against the first side and the bottom of the chamber.

3. The apparatus of claim 1, wherein the shadow frame is offset within the chamber body such that the shadow frame is spaced from the chamber body along the first side by a second distance that is less than a third distance that the shadow frame is spaced from the chamber body along the second side.

4. The apparatus of claim 3, wherein the second distance is substantially equal to a fourth distance that is between the shadow frame and the one or more ledges when the shadow frame is in the second position.

5. The apparatus of claim 1, wherein the one or more ledges spans across substantially the entire length of the slit valve opening.

6. The apparatus of claim 1, wherein the first liner further comprises a second liner portion flush against the second side and extending to a second height greater than the first height.

7. The apparatus of claim 1, further comprising:
a susceptor disposed in the chamber body; and
one or more grounding straps coupled to a bottom surface of the susceptor and the bottom of the chamber.

8. The apparatus of claim 7, wherein the one or more grounding straps are coupled to the bottom surface of the susceptor at a corner or side thereof.

9. The apparatus of claim 1, wherein the first chamber liner is additionally coupled to a third side of the chamber body adjacent to the first side and to a fourth side of the chamber body disposed opposite to the first side.

10. The apparatus of claim 9, further comprising a second chamber liner flush against the first side and the bottom of the chamber.

11. The apparatus of claim 1, wherein the chamber body has a pumping port therethrough, the pumping port disposed through the bottom of the chamber body.

12. The apparatus of claim 1, wherein a distance between the shadow frame and the first liner portion when the shadow frame is in the second position is less than a distance between the first liner portion and the corresponding chamber side.

13. An apparatus, comprising:
a liner assembly comprising a first side having a slit valve opening therethrough, a first top surface, and a first bottom surface, the liner assembly also comprising a second side having a second top surface at substantially the same elevation as the first top surface, and a second bottom surface having an elevation above the first bottom surface, the second side also having an upper portion and a bottom portion spaced therefrom and coupled together at ends of the second side; and
a shadow frame movable between a first position in contact with the liner assembly and a second position spaced form the liner assembly, the shadow frame having a first width that is substantially equal along three sides thereof and a second width along a fourth side thereof that is greater than the first width.

14. The apparatus of claim 13, wherein the liner assembly further comprises a third side disposed opposite to the second side, the third side is substantially identical to the second side.

15. The apparatus of claim 14, wherein the liner assembly further comprises a fourth side adjacent to the second side and the third side, the fourth side substantially identical to the second and third sides.

16. The apparatus of claim 13, further comprising one or more ledges coupled to the first side and disposed above the slit valve opening.

17. The apparatus of claim 16, wherein the one or more ledges span across substantially the entire length of the slit valve opening.

18. A method, comprising:
raising a susceptor from a lowered position to a raised position;
lifting a shadow frame from a first position in contact with a chamber liner to a second position in contact with the susceptor and spaced from the chamber liner such that a first distance between the chamber liner and a chamber wall is greater than a second distance between the shadow frame and the chamber liner; and
pulling processing gas around the shadow frame and between the liner and the chamber wall to an area under the susceptor.

19. The method of claim 18, the lifting further comprising raising the shadow frame from the first position in contact with a shadow frame ledge disposed over the slit valve opening to the second position spaced from the shadow frame ledge such that the shadow frame is spaced a third distance from the shadow frame ledge.

20. The method of claim 19, wherein the third distance and the second distance are substantially equal.
